(19) United States
(12) Patent Application Publication
(10) Pub. No.: US 2024/0327679 A1
(43) Pub. Date: Oct. 3, 2024

(54) MEDIA TRAY WITH SWITCHABLE ADHESION

(71) Applicant: Intel Corporation, Santa Clara, CA (US)

(72) Inventors: Yuan MENG, Chandler, AZ (US); Elizabeth NOFEN, Phoenix, AZ (US); Zhixin XIE, Chandler, AZ (US); Dingying XU, Chandler, AZ (US); Seyed Hadi ZANDAVI, Phoenix, AZ (US)

(21) Appl. No.: 18/194,395

(22) Filed: Mar. 31, 2023

(51) Int. Cl. C09J 7/38; C09J 11/04; H05K 13/00

(52) U.S. Cl. CPC C09J 7/38; C09J 11/04; H05K 13/0069; C09J 2301/408

(57) ABSTRACT

This disclosure describes systems, methods, and devices related to switchable adhesion. A switchable adhesion system may comprise a shape memory polymer having a shaped surface to enhance adhesion using a trigger and a force applied to the shape memory polymer, wherein the trigger is applied to alter characteristics of the shape memory polymer, and wherein the force is applied to deform the shape memory polymer while the trigger is applied. The system may further comprise a media tray connected to the shape memory polymer.

### TECHNICAL FIELD

This disclosure generally relates to systems and methods for media shipping and, more particularly, to media trays with switchable adhesion.

### BACKGROUND

Tape and reel is the current method for die shipping. This single use shipping method is highly die size specific. It has a high die break risk for large reticle size die, and the media density is not optimized for shipping. There is a need for an effective die shipping method.

### BRIEF DESCRIPTION OF THE DRAWINGS

FIG. 1 depicts an illustrative schematic diagram for a switchable adhesion system, in accordance with one or more example embodiments of the present disclosure.

FIGS. 2A-2B depict illustrative schematic diagrams for a switchable adhesion system, in accordance with one or more example embodiments of the present disclosure.

FIGS. 3A-3B depict illustrative schematic diagrams for a switchable adhesion system, in accordance with one or more example embodiments of the present disclosure.

FIG. 4 depicts an illustrative schematic diagram for a switchable adhesion system, in accordance with one or more example embodiments of the present disclosure.

FIGS. 5A-5B depict illustrative schematic diagrams for a switchable adhesion system, in accordance with one or more example embodiments of the present disclosure.

FIG. 6 illustrates a flow diagram of a process for an illustrative switchable adhesion system, in accordance with one or more example embodiments of the present disclosure.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

A pocket-less, textured media tray, an alternative die handling media with good packing density, allows for the handling of die (e.g., silicon containing an integrated circuit) regardless of the form factor. However, shipping dies using the existing pocket-less, textured media tray method is susceptible to yield loss as the die will move during shipping, as a result of the limited adhesion between the tray substrate and the die. There is a need for a practical media/carrier solution with tunable shear and pickup adhesion at a relatively low cost, for tray-level die-handling applications.

Die shipping is currently performed by tape and reel, where dies are placed into a pocket of a thermoformed reel and sealed with a thermal adhesive. A pocket-less, textured media tray is an emerging technology for die handling which is composed of a tacky surface inside a pocketless tray structure. A textured thermoplastic elastomer is employed as part of the tray media to allow for enough “tack” to hold the die in place. It allows for the handling of a die regardless of form factor. Although the tape and reel approach is proven to work with traditional die, it has limitations over form factors that can be handled or shipped. Larger die sizes, for example, 2× and 4× reticle dies, are not compatible with tape and reel due to the curvature restriction imposed by the reel. Also, the packaging density of the tape and reel technology is low and the technology allows for only single use. The pocket-less, textured media tray technology is susceptible to yield loss if the die moves during shipping, as a result of the low adhesion between the die and the tray substrate surface, thus new solutions are required.

Example embodiments of the present disclosure relate to systems, methods, and devices for media trays with switchable adhesion based on structured shape memory polymer.

In one or more embodiments, a switchable adhesion system may utilize a shape memory polymer (SMP) based tray that provides a strong adhesion force large enough to hold the die still during shipping, regardless of the die form factor. SMP can remember its permanent shape, however, it can be deformed and held in a secondary shape. SMP can be conveniently triggered by external stimuli (e.g., light, heat, moisture, magnetic field, etc.) to shift its shape and release dies from the tray. Here a patterned SMP layer will be applied inside a tray, that will allow for reliable, repeated die pick and place operations onto and off the tray. The SMP layer goes through shape-memory cycles, being locked in a temporarily deformed state of a large contact area with the die, it provides large enough adhesion during shipping for a large range of die sizes. The SMP can be triggered to get back to a permanent state with limited contact area (and minimum adhesion) for die release and it leaves no adhesive residue on the die. The adhesion force is determined on the level of feature deformation, and thus provides a broad range of tunable adhesion. This clean and reliable media technology is an automated material handling system (AMHS)-capable and can work from start to finish throughout the shipping and assembly/test flow.

In one or more embodiments, a switchable adhesion system may facilitate that a textured shape memory polymer layer may be placed on a tray structure. A plurality of microelectronic components of a variety of sizes can be mechanically and removably coupled to the texturized SMP surface, without the need for any additional stabilization methods. This unique SMP-based tray structure allows for a secure media that prevent die movement during shipping or other assembly/test applications.

SMP tray is compatible with a wide range of die ratios and sizes for current and next-generation development and gives “unlimited” die picking cycles with no sear time restrictions for storage. This novel tray approach, once going through the shape memory cycle, allows for large enough adhesion that avoids unwanted die movement during shipping. The textured film features contact adhesion which leaves no residue on the shipped die and can handle either the die or packages in the tray. If contaminated, the SMP-based tray can be cleaned with isopropyl alcohol (IPA) or deionized water (DIW), and can be reused until the tray or film is damaged giving a low cost of ownership. The technology requires a millimeter-scaled feature size, so can be manufactured at a rather low cost. The reversible adhesion is triggered with heating and cooling, so can be engineered to be infrared-triggered. Importantly, this AMHS-capable media can be kept throughout the flow from die transport to thermo-compression bonding (TCB) chip attach, avoiding frequent carrier/media transfer which is currently required.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

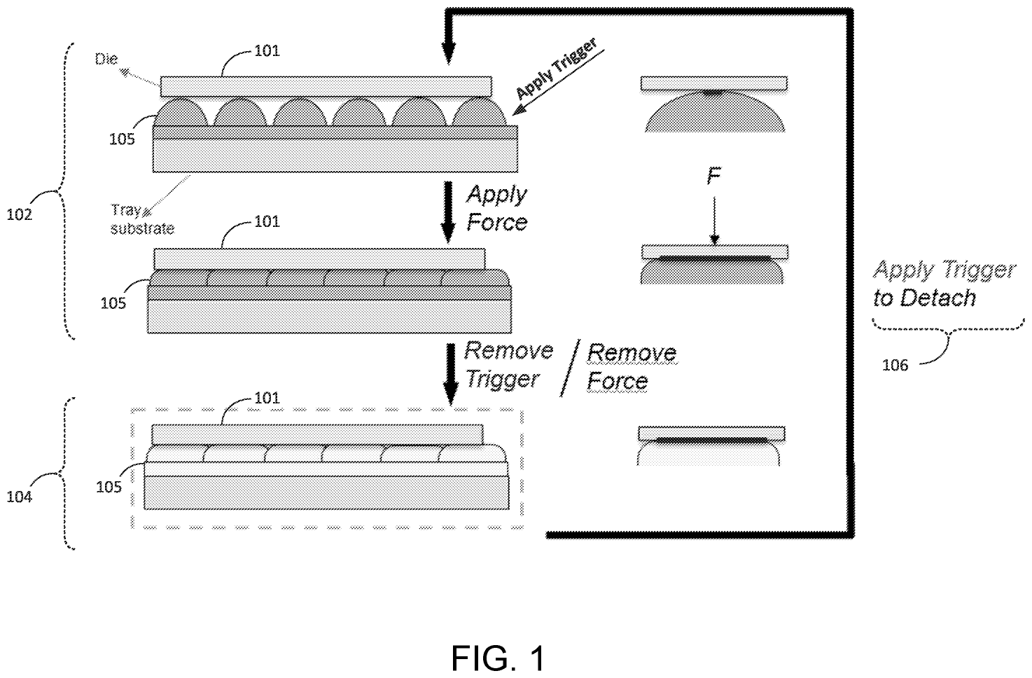

FIG. 1 depicts an illustrative schematic diagram for a switchable adhesion system, in accordance with one or more example embodiments of the present disclosure.

Referring to FIG. 1, there is shown a mechanism of a shape memory polymer tray for die shipping. The change of contact area in different states of the shape memory cycle gives rise to reversible adhesion force to the attached dies.

In one or more embodiments, a switchable adhesion system may facilitate that a trigger (e.g., heat, light, moisture, magnetic field, etc.) may be applied (in step 102) to the structure 105 made from SMP material or similar material. Force may then be applied to the die 101 sitting on top of the structure 105 in order to transform the structure 105 into a temporary shape. This results in the die 101 being in contact with the structure 105 at a larger contact surface because of the buckling or deforming of the structure 105 due to the application of the trigger and the force. Because it is deformed due to the applied trigger and force, the structure 105 will have a larger contact area with the die 101 resulting in an increased adhesion force. Then the trigger may be removed in order to hold the structure in the temporary shape (as seen in step 104) while gripping the die 101 in place. For example, in case the trigger is heat, when heat is removed, the structure 101 may hold its secondary shape while having adhesion to the die 101, thus holding the die 101 in place for shipping. As seen in step 106, once the die 101 needs to be released from the structure 105, the trigger may be applied again to the structure 105 in order to trigger the memory effect and detach from the die 101. For example, in case the trigger is heat, when heat is applied again after the shipping is completed or when the die 101 is to be removed from the tray, the structure 105 may return to its original form and create a minimal contact area with the die 101 such that the die 101 can be easily removed from the tray. In other words, after the application of the trigger, the structure 105 will return to its original form which in turn minimizes its contact area with the die 101 and lower the adhesion force between the die 101 and the structure 105 in order to remove the die 101 from the tray.

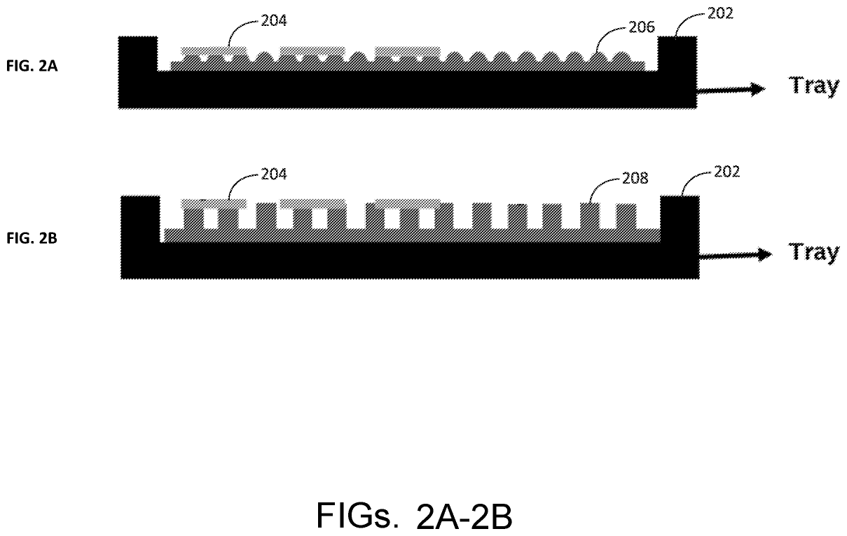

FIGS. 2A-2B depict illustrative schematic diagrams for a switchable adhesion system, in accordance with one or more example embodiments of the present disclosure.

Referring to FIG. 2, there is shown an SMP tray structure 202 for die shipping (e.g., die 204). Shape-memory polymers (SMPs) are polymers that can be deformed and temporarily fixed into an elastically strained, non-equilibrium shape. Shape fixing can be achieved via the formation of temporary bonding, that can be triggered to be removed through heating, light exposure, electrical/magnetic field application, and so on. Regardless of how shape-fixing is accomplished, elastic energy is stored until the SMP is triggered, and can be utilized to do work upon release. The modulation of interfacial adhesion can be achieved with structured SMPs that can be triggered using external stimuli to change their shape and contact area, and thus allow for tunable dry adhesion. Since contact adhesion is based on Van der Waal force, SMP as an adhesive leaves no residue on the substrate. This concept can be conveniently employed to tune the surface contact and carrier-die adhesion in a media tray, allow for strong bonding during shipping, and low adhesion to pick and handle when needed.

Various shapes of the SMP structure may have different adhesion effects when a trigger and force are applied to the die. For example, the pillar structure shown in FIG. 2B may experience a buckling effect that may cause an adhesion effect that may be different than the adhesion effect on the dome structure shown in FIG. 2A. For example, die 204 may adhere to a structure (e.g., structured SMP 206 of FIG. 2A or structured SMP 208 of FIG. 2B) when a trigger and force are applied in order to achieve an adhesion force large enough to hold the die 204 for shipping, regardless of the die form factor. The two examples of the structure (e.g., structured SMPs 206 and 208) can remember their permanent shape and can be deformed and held in a second shape when force is applied to the die to push it onto the structure. Structured SMPs 206 and 208 can be conveniently triggered by external stimuli (e.g., light, heat, moisture, magnetic field, etc.) to shift their shape and release the die 204 from the tray.

Material modulus as well as featured pattern geometry determine the preload required to bond the die onto the SMP tray.

In one or more embodiments, a structure layer (e.g., an SMP structure layer or another type of structure) may have adhered to a standard, flat media tray base, and dies may be attached on top of the SMP layer to allow for directionally controlled adhesion behaviors. The attached die will experience high shear adhesion, enabling safe die shipping, whereas low enough normal adhesion upon triggered SMP release to guarantee successful pick-up for follow-up processes. The high contact adhesion is overcome by the released elastic energy of the SMP, in order to achieve tunable dry adhesion. The patterned structure of SMP can be a pillar shape, mushroom shape, half-sphere shape, or many other shapes. The feature size of the SMP structure can span in the critical dimension range of 100 um-10 mm, giving rise to a spectrum of tunable adhesion behaviors. Importantly, the SMP tray technology does not leave any residue on the backside of the attached die and can handle either the die or packages in the tray. If contaminated, the SMP tray can be conveniently cleaned with IPA or DIW.

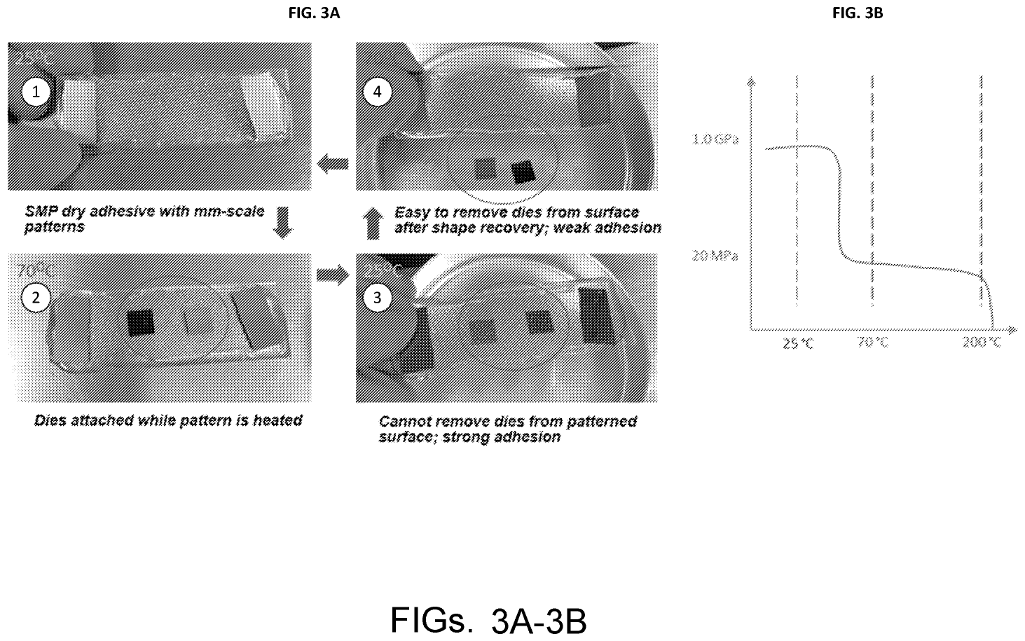

FIGS. 3A-3B depict illustrative schematic diagrams for a switchable adhesion system, in accordance with one or more example embodiments of the present disclosure.

Referring to FIG. 3A, there is shown a proof-of-concept process to demonstrate the reversible adhesion capability of a structure (in this example it is an SMP structure) for die shipping application. A structured SMP film with a millimeter (mm) scale half-sphere feature size was molded using a thermoplastic polyurethane (1). The SMP can be thermal-triggered and has a transition temperature of 50 degrees Celsius. It has a high modulus of 1.0 gigapascal (GPa) below its transition, and becomes elastic and deformable with a modulus of 20 MPa above its transition (as shown in FIG. 3B). Two 10×10 mm dies are attached to the SMP surface while the pattern is heated and soft (2). The system is cooled down to room temperature, and the dies stick to the surface with strong contact adhesion (well above the required adhesion to prevent die movement during shipping applications), it is difficult to remove the dies from the SMP surface without breaking the dies (3). In the example where the trigger is heat, after reheating the system above the transition temperature, the structure may be deformed (the SMP structure layer) and may be triggered to return to its original form. This results in a minimum contact area with the dies. Subsequently, the dies may be released from the structure surface (e.g. the SMP structure), which results in no resistance for picking the dies from the structure surface (4). This process of picking up and placing the die for shipping was demonstrated to work with high fidelity for at least 10 times.

It is understood that the above descriptions are for purposes of illustration and are not meant to be limiting.

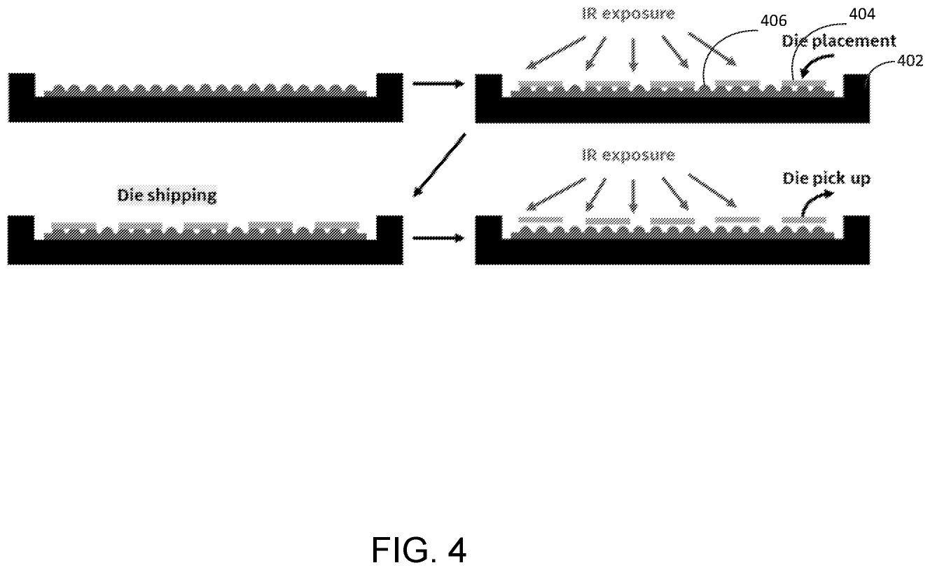

FIG. 4 depicts an illustrative schematic diagram for a switchable adhesion system, in accordance with one or more example embodiments of the present disclosure.

Referring to FIG. 4, there is shown a process flow to place and pick up dies (e.g., dies 404) onto a tray 402 comprising a structure layer (e.g., SMP structure 408) using IR as a trigger. After IR exposure, the dies 404 may be pressed onto the structure layer using force.

In the example elf FIG. 4, an SMP layer is proposed as a die shipping method using a tray that makes use of the shape memory effect to modulate surface contact area with attached dies 404, and thus can be comprised of, but not limited to, any polymer materials with a well-defined transition (crystallization, glass transition, hydrogen bonding, etc), including conventional thermoplastics polyurethane, acrylates, polyimides, fluoropolymers (PTFE, fluororubber), thermosets (epoxy, PU, silicone), thermoplastic elastomers, semi-crystalline polymer and so on. Different choice of thermally-triggered SMP gives rise to a very wide range of triggering temperature from 20 C to 200 C. With the addition of carbon black or gold nanoparticle into the thermal SMP formulation, the shape memory effect can be conveniently triggered with infrared exposure as well, which appeals to high-volume process flows.

It is understood that the above descriptions are for purposes of illustration and are not meant to be limiting.

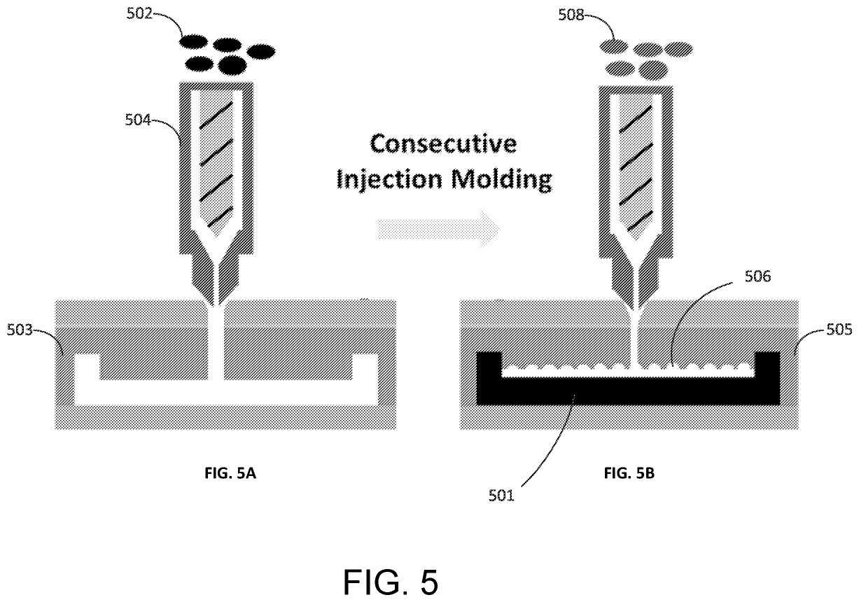

FIGS. 5A-5B depict illustrative schematic diagrams for a switchable adhesion system, in accordance with one or more example embodiments of the present disclosure.

Referring to FIGS. 5A and 5B, there is shown a 2-shot injection molding process to first fabricate the tray 501 and then fabricate the SMP film layer 506 using materials 502 and 508, respectively.

In one or more embodiments, depending on the material choice of the SMP film layer 506, a variety of low-cost manufacturing methods can be utilized, including injection molding, roll-to-roll embossing, lamination, template casting, etc. For example, to fabricate an SMP tray with the micro-scaled feature, a simple 2-shot injection approach can be conveniently implemented. The shear adhesion achieved for a typical pocket-less, textured media tray is <10 kPa, and an additional anchoring setup is still required to further stabilize the die. However, with significantly larger shear adhesion, an SMP tray (without additional setup) exhibits an enhanced capability to prevent die movement during shipping. Application of the SMP based dry adhesive can be expanded for wafer, panel, and tray level die handling as well, given the strong adhesion, triggered release, and a broad range of materials choice.

In FIG. 5A, a polycarbonate (PC) material may be injected into mold 503 to create the tray 501. After the creation of tray 501 using mold 503, a consecutive injection may be performed in order to fabricate the SMP film layer 506.

Referring to FIG. 5B, a thermoplastic elastomers (TPE) material may be injected into mold 505 to fabricate the SMP film layer 506.

It is understood that the above descriptions are for purposes of illustration and are not meant to be limiting.

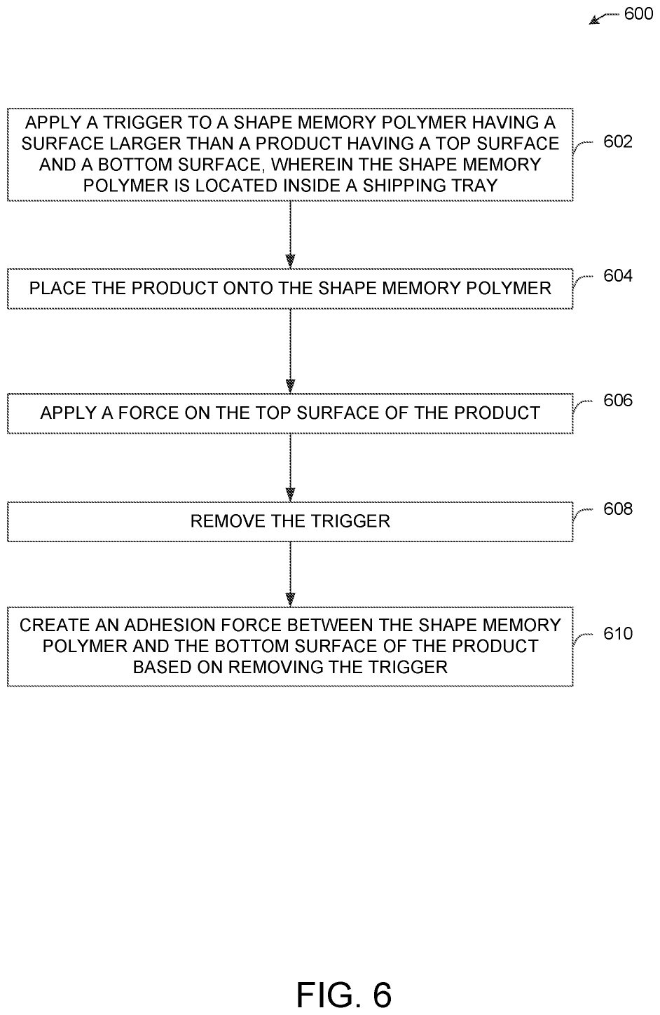

FIG. 6 illustrates a flow diagram of a process 600 for a switchable adhesion system, in accordance with one or more example embodiments of the present disclosure.

In some embodiments, the switchable adhesion system may be configured to perform one or more processes, techniques, or methods as described herein, or portions thereof. One such process is depicted in FIG. 3.

For example, the process may include, at 602, applying a trigger to a shape memory polymer having a surface larger than a product having a top surface and a bottom surface, wherein the shape memory polymer is located inside a media tray.

The process further includes, at 604, placing the product onto the shape memory polymer.

The process further includes, at 606, applying a force on the top surface of the product.

The process further includes, at 608, removing the trigger.

The process further includes, at 610, creating an adhesion force between the shape memory polymer and the bottom surface of the die product based on removing the trigger.

It is understood that the above descriptions are for purposes of illustration and are not meant to be limiting.

The word “exemplary” is used herein to mean “serving as an example, instance, or illustration.” As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

Some embodiments may be used in conjunction with various devices and systems, for example, a personal computer (PC), a desktop computer, a mobile computer, a laptop computer, a notebook computer, a tablet computer, a server computer, a handheld computer, a handheld device, a personal digital assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless access point (AP), a wired or wireless router, a wired or wireless modem, a video device, an audio device, an audio-video (A/V) device, a wired or wireless network, a wireless area network, a wireless video area network (WVAN), a local area network (LAN), a wireless LAN (WLAN), a personal area network (PAN), a wireless PAN (WPAN), and the like.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

One general aspect includes a system. The system also includes a shape memory polymer having a shaped surface to enhance adhesion using a trigger and a force applied to the shape memory polymer, where the trigger is applied to alter characteristics of the shape memory polymer, and where the force is applied to deform the shape memory polymer while the trigger is applied. The system also includes a media tray connected to the shape memory polymer. Other embodiments of this aspect include corresponding computer systems, apparatus, and computer programs recorded on one or more computer storage devices, each configured to perform the actions of the methods.

Implementations may include one or more of the following features. The system where altering the characteristics of the shape memory polymer causes a shift in the shape of the shape memory polymer from a primary shape to a secondary shape. The shaped surface is shaped as a circle shape, a pillar shape, a concave shape, or a convex shape. The trigger is light, heat, moisture, or a magnetic field. An adhesion force is determined based on a level of formation of the shape memory polymer. The shape memory polymer is locked into a secondary shape after the removal of the trigger. Reapplying the trigger causes a shift from the secondary shape to the primary shape of the shape memory polymer. The shape memory polymer may include at least one of conventional thermoplastics polyurethane, acrylates, polyimides, fluoropolymers, thermosets, thermoplastic elastomers, or semi-crystalline polymer. Implementations of the described techniques may include hardware, a method or process, or computer software on a computer-accessible medium.

One general aspect includes a method. The method includes applying a trigger to a shape memory polymer having a surface larger than a product having a top surface and a bottom surface, where the shape memory polymer is located inside a media tray. The method also includes placing the product onto the shape memory polymer. The method also includes applying a force on the top surface of the product. The method also includes removing the trigger. The method also includes creating an adhesion force between the shape memory polymer and the bottom surface of the product based on removing the trigger. Other embodiments of this aspect include corresponding computer systems, apparatus, and computer programs recorded on one or more computer storage devices, each configured to perform the actions of the methods.

Implementations may include one or more of the following features. The method where the product is a silicon may include an integrated circuit. The shape memory polymer has a top surface shaped as part of a circle, a pillar, a concave, or a convex shape. The trigger is light, heat, moisture, or a magnetic field. The adhesion force is determined based on a level of formation of the shape memory polymer. The shape memory polymer is locked into a secondary shape after the removal of the trigger. The method may include releasing the product from the shape memory polymer by reapplying the trigger. The shape memory polymer may include at least one of conventional thermoplastics polyurethane, acrylates, polyimides, fluoropolymers, thermosets, thermoplastic elastomers, or semi-crystalline polymer. The shape memory polymer contains carbon black or gold nanoparticle. Implementations of the described techniques may include hardware, a method or process, or computer software on a computer-accessible medium.

One general aspect includes an apparatus. The apparatus also includes a shape memory polymer having a shaped surface to enhance adhesion using a trigger applied to the shape memory polymer. The apparatus also includes a product having a top surface and a bottom surface, where the bottom surface is in contact with the shaped surface of the shape memory polymer, where a force is applied on the top surface of the product to deform the shape memory polymer, and where the bottom surface of the product adheres to the shaped surface of the shape memory polymer after removal of the trigger. The apparatus also includes a media tray connected to the shape memory polymer to carry the product. Other embodiments of this aspect include corresponding computer systems, apparatus, and computer programs recorded on one or more computer storage devices, each configured to perform the actions of the methods.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Certain aspects of the disclosure are described above with reference to block and flow diagrams of systems, methods, apparatuses, and/or computer program products according to various implementations. It will be understood that one or more blocks of the block diagrams and flow diagrams, and combinations of blocks in the block diagrams and the flow diagrams, respectively, may be implemented by computer-executable program instructions. Likewise, some blocks of the block diagrams and flow diagrams may not necessarily need to be performed in the order presented, or may not necessarily need to be performed at all, according to some implementations.

These computer-executable program instructions may be loaded onto a special-purpose computer or other particular machine, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable storage media or memory that may direct a computer or other programmable data processing apparatus to function in a particular manner, such that the instructions stored in the computer-readable storage media produce an article of manufacture including instruction means that implement one or more functions specified in the flow diagram block or blocks. As an example, certain implementations may provide for a computer program product, comprising a computer-readable storage medium having a computer-readable program code or program instructions implemented therein, said computer-readable program code adapted to be executed to implement one or more functions specified in the flow diagram block or blocks. The computer program instructions may also be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A system, comprising:
a shape memory polymer having a shaped surface to enhance adhesion using a trigger and a force applied to the shape memory polymer, wherein the trigger is applied to alter characteristics of the shape memory polymer, and wherein the force is applied to deform the shape memory polymer while the trigger is applied; and
a media tray connected to the shape memory polymer.

2. The system of claim 1, wherein altering the characteristics of the shape memory polymer causes a shift in the shape of the shape memory polymer from a primary shape to a secondary shape.

3. The system of claim 1, wherein the shaped surface is shaped as a circle shape, a pillar shape, a concave shape, or a convex shape.

4. The system of claim 1, wherein the trigger is light, heat, moisture, or a magnetic field.

5. The system of claim 1, wherein an adhesion force is determined based on a level of formation of the shape memory polymer.

6. The system of claim 1, wherein the shape memory polymer is locked into a secondary shape after the removal of the trigger.

7. The system of claim 6, wherein reapplying the trigger causes a shift from the secondary shape to a primary shape of the shape memory polymer.

8. The system of claim 1, wherein the shape memory polymer comprises at least one of conventional thermoplastics polyurethane, acrylates, polyimides, fluoropolymers, thermosets, thermoplastic elastomers, or semi-crystalline polymer.

9. The system of claim 1, wherein the shape memory polymer contains carbon black or gold nanoparticle.

10. A method comprising:
applying a trigger to a shape memory polymer having a surface larger than a product having a top surface and a bottom surface, wherein the shape memory polymer is located inside a media tray;
placing the product onto the shape memory polymer;
applying a force on the top surface of the product; and
removing the trigger; and
creating an adhesion force between the shape memory polymer and the bottom surface of the product based on removing the trigger.

11. The method of claim 10, wherein the product is a silicon comprising an integrated circuit.

12. The method of claim 10, wherein the shape memory polymer has a top surface shaped as part of a circle, a pillar, a concave, or a convex shape.

13. The method of claim 10, wherein the trigger is light, heat, moisture, or a magnetic field.

14. The method of claim 10, wherein the adhesion force is determined based on a level of formation of the shape memory polymer.

15. The method of claim 10, wherein the shape memory polymer is locked into a secondary shape after the removal of the trigger.

16. The method of claim 10, further comprising releasing the product from the shape memory polymer by reapplying the trigger.

17. The method of claim 10, wherein the shape memory polymer comprises at least one of conventional thermoplastics polyurethane, acrylates, polyimides, fluoropolymers, thermosets, thermoplastic elastomers, or semi-crystalline polymer.

18. The method of claim 10, wherein the shape memory polymer contains carbon black or gold nanoparticle.

19. An apparatus comprising:
a shape memory polymer having a shaped surface to enhance adhesion using a trigger applied to the shape memory polymer;
a product having a top surface and a bottom surface, wherein the bottom surface is in contact with the shaped surface of the shape memory polymer, wherein a force is applied on the top surface of the product to deform the shape memory polymer, and wherein the bottom surface of the product adheres to the shaped surface of the shape memory polymer after removal of the trigger; and
a media tray connected to the shape memory polymer to carry the product.

20. The apparatus of claim 19, wherein the trigger is light, heat, moisture, or a magnetic field.
